(19) United States
(12) Patent Application Publication
(10) Pub. No.: US 2023/0369949 A1
(43) Pub. Date: Nov. 16, 2023

(54) MOTOR CONTROLLER WITH POWER MODULE TRANSVERSE TO BOARD

(71) Applicant: Nidec Motor Corporation, St. Louis, MO (US)

(72) Inventors: Prakash B. Shahi, St. Louis, MO (US); Victor Hugo Dos Santos, Santa Catarina (BR); Marcelo Alessandro Santos, Santa Catarina (BR); Douglas D. Glenn, Highland, IL (US)

(73) Assignee: Nidec Motor Corporation, St. Louis, MO (US)

(21) Appl. No.: 18/191,585

(22) Filed: Mar. 28, 2023

Related U.S. Application Data
(60) Provisional application No. 63/340,287, filed on May 10, 2022.

(51) Int. Cl. H02K 11/33; H05K 7/20

(52) U.S. Cl. CPC H02K 11/33; H05K 7/209; H02K 2211/03

(57) ABSTRACT

An electric motor includes a controller. The controller includes a controller housing presenting a heat sink surface. The controller further includes a printed circuit board and a power module. The printed circuit board is at least substantially disposed within the housing. The power module thermally engages the heat sink surface and is mounted transverse to the printed circuit board.

### CROSS REFERENCE TO RELATED APPLICATION

The present application claims priority from U.S. Provisional Application No. 63/340,287 filed May 10, 2022, entitled MOTOR CONTROLLER WITH POWER MODULE TRANSVERSE TO BOARD, which is hereby incorporated in its entirety by reference herein.

### TECHNICAL FIELD

The present invention relates generally to an electric motor. More particularly, the present invention relates generally to an electric motor having a controller including a printed circuit board and a power module. The power module is mounted transverse to the printed circuit board.

### BRIEF DESCRIPTION OF THE DRAWING FIGURES

Preferred embodiments of the present invention are described in detail below with reference to the attached drawing figures, wherein:

FIG. 1 is a rear perspective view of a prior art motor;

FIG. 2 is a front perspective view of the motor of FIG. 1, with a first endshield removed to particularly illustrate internal motor components;

FIG. 3 is a partially exploded rear perspective view of the motor of FIGS. 1 and 2, particularly illustrating a controller can defining a controller compartment;

FIG. 4 is an enlarged front perspective view of the controller can of FIG. 3, particularly illustrating a metal insert of the controller can and electronic components of a controller disposed in the controller can;

FIG. 5 is a rotated, partially-sectioned front perspective view of the controller can of FIG. 4, particularly illustrating surfaces for conducting heat from at least one of the electronic components to the metal insert;

FIG. 6 is a partially exploded side perspective view of the controller can of FIG. 4, particularly illustrating aspects and contents of the controller can;

FIGS. 7-9 illustrate a single-in-line (SIP) power module at least substantially similar to that of the motor of FIGS. 1-6;

FIG. 10 is a photograph of a controller including a SIP power module at least substantially similar to that of the motor of FIGS. 1-6 and that of FIGS. 7-9;

FIGS. 11-14 illustrate a conventional dual-in-line (DIP) power module with orthogonally projecting pins and configured to be mounted parallel to a printed circuit board;

FIGS. 15 and 16 illustrate a DIP power module with orthogonally projecting pins mounted vertically on a secondary plate connected to a printed circuit board;

FIGS. 17 and 18 illustrate a prior art controller can suited for use with the present invention;

FIGS. 19-24 illustrate a DIP power module in accordance with a first preferred embodiment of the present invention, wherein the power module includes outwardly projecting pins and the upper pins are soldered to associated leads;

FIGS. 25 and 26 illustrate a DIP power module in accordance with a second preferred embodiment of the present invention, wherein the power module includes outwardly projecting bottom pins and bent upper pins, and the upper pins are secured to associated leads via connectors; and

FIGS. 27 and 28 illustrate a DIP power module in accordance with a third preferred embodiment of the present invention, wherein the power module is similar to that of FIGS. 19-24, but with “board-in” terminals for the upper pins and the first ends of associated leads.

The drawing figures do not limit the present invention to the specific embodiments disclosed and described herein. While the drawings do not necessarily provide exact dimensions or tolerances for the illustrated structures or components, the drawings are to scale with respect to the relationships between the components of the structures illustrated in the drawings.

### SUPPLEMENTARY MATERIALS

A motor controller can including numerous features suitable for use with the present invention is illustrated and described in U.S. Pat. Application No. 16/925,510, filed Jul. 10, 2020, and entitled “MOTOR CONTROLLER CAN WITH SYNTHETIC HOUSING AND METAL HEAT SINK,” the entire disclosure of which is hereby incorporated by reference herein.

### DETAILED DESCRIPTION

The present invention is susceptible of embodiment in many different forms. While the drawings illustrate, and the specification describes, certain preferred embodiments of the invention, it is to be understood that such disclosure is by way of example only. There is no intent to limit the principles of the present invention to the particular disclosed embodiments.

Furthermore, unless specified or made clear, the directional references made herein with regard to the present invention and/or associated components (e.g., top, bottom, upper, lower, inner, outer, etc.) are used solely for the sake of convenience and should be understood only in relation to each other. For instance, a component might in practice be oriented such that faces referred to as “top” and “bottom” are sideways, angled, inverted, etc. relative to the chosen frame of reference.

### Prior Art Motor With SIP Power Module

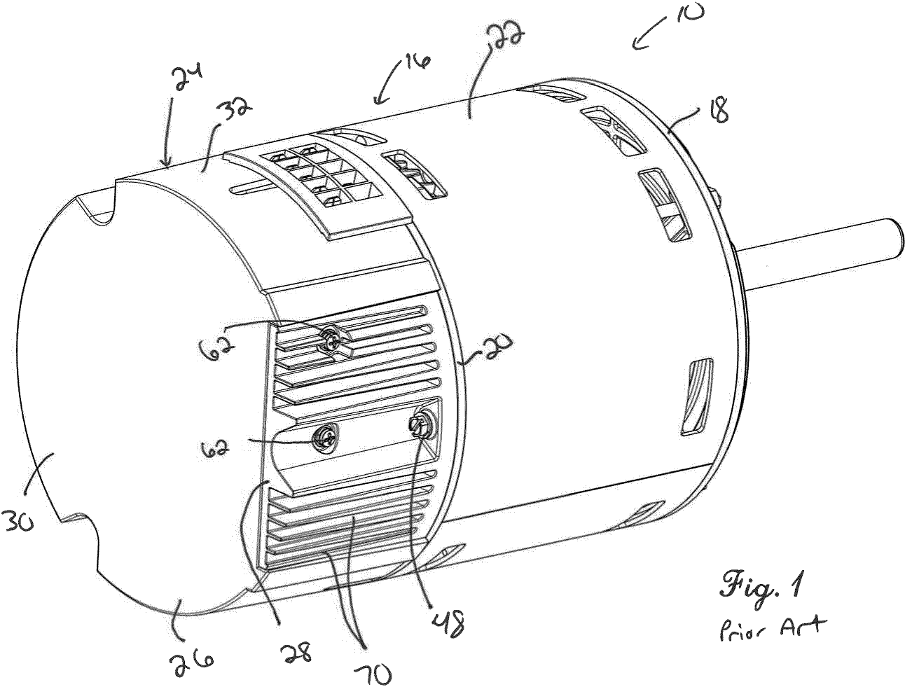

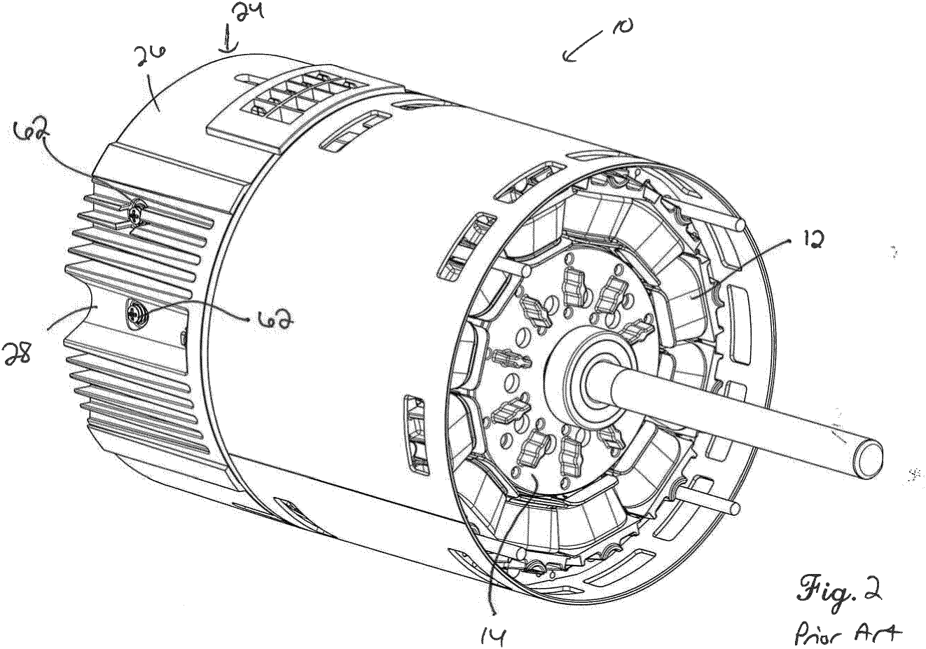

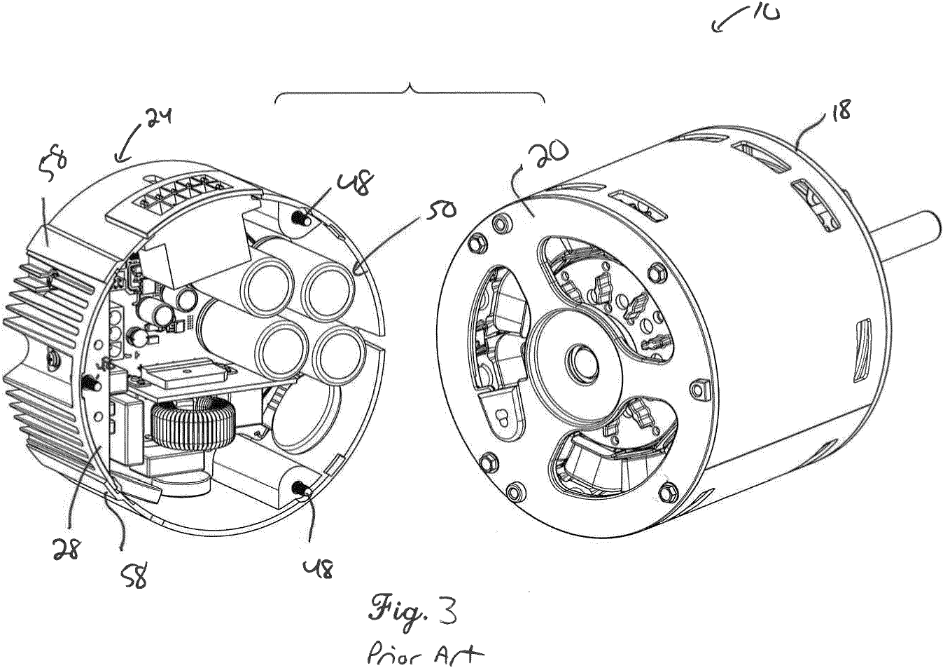

With initial reference to FIGS. 1-6, a prior art motor 10 is illustrated. The motor 10 includes a stator 12 and a rotor 14. The motor 10 further includes a motor housing 16 broadly including a first endshield 18, a second endshield 20, a shell 22 extending between the endshields 18 and 20, and a controller can 24.

The controller can 24 preferably includes a can housing 26 and a metal insert 28. The can housing 26 includes a generally radially extending end plate 30 and a generally axially extending skirt 32 projecting transversely from the end plate 30 toward the shell 22.

Preferably, the motor 10 includes fasteners 48 that extend through and interconnect the second endshield 20 and the can 24. At least one of the fasteners 48 additionally extends through the metal insert 28 to hold the metal insert 28 against the second endshield 20.

The motor 12 preferably also includes a controller 50. In a preferred embodiment, the controller 50 includes a substantially planar printed circuit board (PCB) 52. The controller 50 further preferably includes a plurality of electronics components 54 mounted on the PCB 52. The electronics components 54 may include primary control and/or pilot control devices, such as a power module (discussed in more detail below), a motor starter, float switches, pressure switches, magnetic contactors, contactor coils, circuit breakers and/or overload relays. However, any of a variety of controller types, configurations and components are permissible according to some aspects of the present invention.

The can 24 preferably partly or completely defines a controller compartment 56 in which the controller 50 is disposed. More particularly, the skirt 32 and the metal insert 28 cooperatively at least substantially circumscribe the controller 50, with the controller 50 being disposed axially between the end plate 30 and the second endshield 20.

The can housing 26 preferably includes two pairs of arcuately spaced apart, opposing flanges 58 extending generally axially along either side of an opening 60 in the can housing 26. The opposing flanges 58 are configured to receive the metal insert 28 therebetween (that is, at least in part in the opening 60) and at least partly secure the metal insert 28 against radial and/or circumferential movement with respect to the housing 26.

The metal insert 28 is also secured to the can housing 26 and/or components 54 housed therein by fasteners 62, which may substantially restrict axial movement of the metal insert 28 with respect to the skirt 32. Fasteners 62 preferably comprise bolts, though it is foreseen that any one or more of a variety of fasteners or other connection types — for example, buckles, clamps, clasps, clips, latches, nails, pins, rings, straps, welds and/or friction fits — may be employed without departing from the spirit of the present inventive concept. The fasteners 62 may assist with thermal transfer between the controller 50 and the metal insert 28, and/or may provide grounding for the controller 50 to assist with controlling EMI emissions. The fasteners 62 therefore preferably comprise thermally and/or electrically conductive metal(s).

In the preferred embodiment, the fasteners 62 may be directly or indirectly fixed to a power module 64 (described below) of the controller 50 for transferring heat and/or EMI emissions to the insert 28 and/or an exterior of the can 24.

The metal insert 28 is preferably exposed to the exterior of the can 24, which may be an ambient environment and/or other heat sink. That is, the exterior of the can 24 is preferably capable of acting as a heat sink to absorb heat in order to support rapid heat transfer from the can 24 to an external heat sink space.

In the illustrated embodiment, the power module 64 of the components 54 abuts and is thermally connected to the metal insert 28. That is, the power module 64 transfers thermal energy to the metal insert 28 directly through conductive contact and/or indirectly via conductive contact with one or more intermediaries having relatively favorable heat transfer properties and dimensions for heat transfer. More preferably, the heat transfer properties of any such intermediary are at least as conducive to heat transfer as the material(s) comprising the metal insert 28, and are dimensioned so as to provide for efficient heat transfer to the metal insert 28.

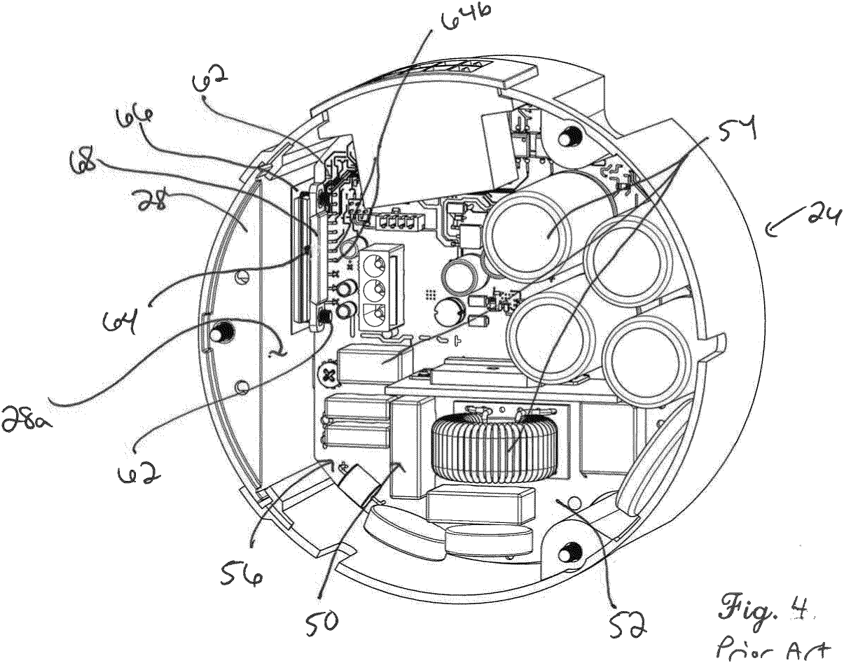

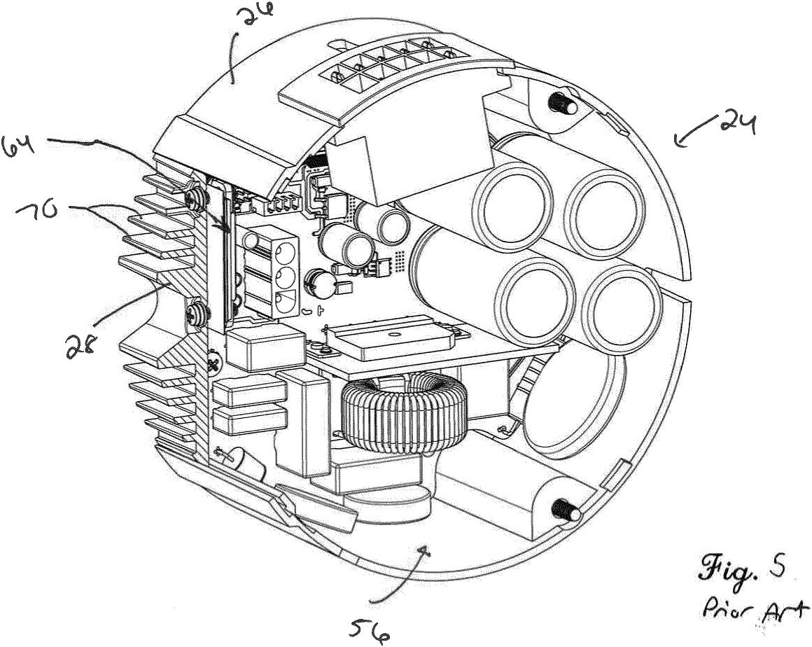

More particularly, the metal insert 28 preferably includes a substantially planar interior surface 28a (see FIG. 4). Power module 64 preferably includes a broad, and preferably substantially planar, outward-facing surface 64a (see FIG. 6) that sits adjacent and substantially parallel to the interior surface 28a. Sandwiched between the power module 64 and the metal insert 28 is preferably a thermal conductive sheet 66 for absorbing heat from the power module 64 and distributing same across a broader surface area along the interface with interior surface 28a of the metal insert 28.

The power module 64, conductive sheet 66, and metal insert 28 are preferably fixed together by the aforementioned fasteners 62. More particularly, in the illustrated embodiment, the fasteners 62 extend through two aligned sets of holes formed through the metal insert 28 and through opposing sides of the conductive sheet 66 and power module 64. Interior ends of the fasteners 62 may be secured to a rigid strip or mounting bar 68 inside the controller compartment 56. For instance, the fasteners 62 may comprise threaded bolts received within correspondingly threaded apertures defined by the rigid strip 68. The rigid strip 68 may be at least as wide as the power module 64, and may be formed of insulative material. The PCB 52, components 54, power module 64 and/or the planar surface 28a can be selectively positioned at a plurality of locations relative to the metal insert 28.

The rigid strip 68 may substantially hold the power module 64 against the conductive sheet 66, thereby helping to maintain efficient heat transfer therebetween. The rigid strip 68 may also inhibit heat transfer into the controller compartment 56, at least by covering a portion of an inner face of the power module 64 with insulative material. In an embodiment, such insulative material may comprise the material that forms the can housing 26. It is foreseen that other means of fastening and/or maintaining conductive contact between a metal insert and heat and/or EMI source(s) within a controller compartment may be employed without departing from the spirit of the present inventive concept.

The metal insert 28 preferably also defines a plurality of heat transfer fins 70. The fins 70 are configured to disperse heat from the controller compartment or chamber 56.

The can housing 26 material may be selected from a group of materials having relatively low heat conductivity. More particularly, each such material may be selected for its ability to remain at or below a certain temperature during operation of motor 12, thereby preventing heat damage that may otherwise be caused by proximity of the can housing 26 (for example, an inner surface of end plate 30) to the controller 50 (for example, to traces of the PCB 52 and/or components 54). Preferably, the can housing 26 may comprise a plastic. More preferably, the can housing 26 comprises a polycarbonate.

In contrast, the material of the metal insert 28 is preferably selected from a group of metals having relatively high thermal conductivity. More particularly, each such metal is preferably selected for its ability to transfer heat efficiently and quickly from the controller compartment 56 to the external heat sink space.

The power module 64 is a single-in-line (SIP) power module. More particularly, the power module 64 is soldered or attached electrically through in-line pins 64b (see FIGS. 4 and 6) on one end only.

### Prior Art SIP Power Modules

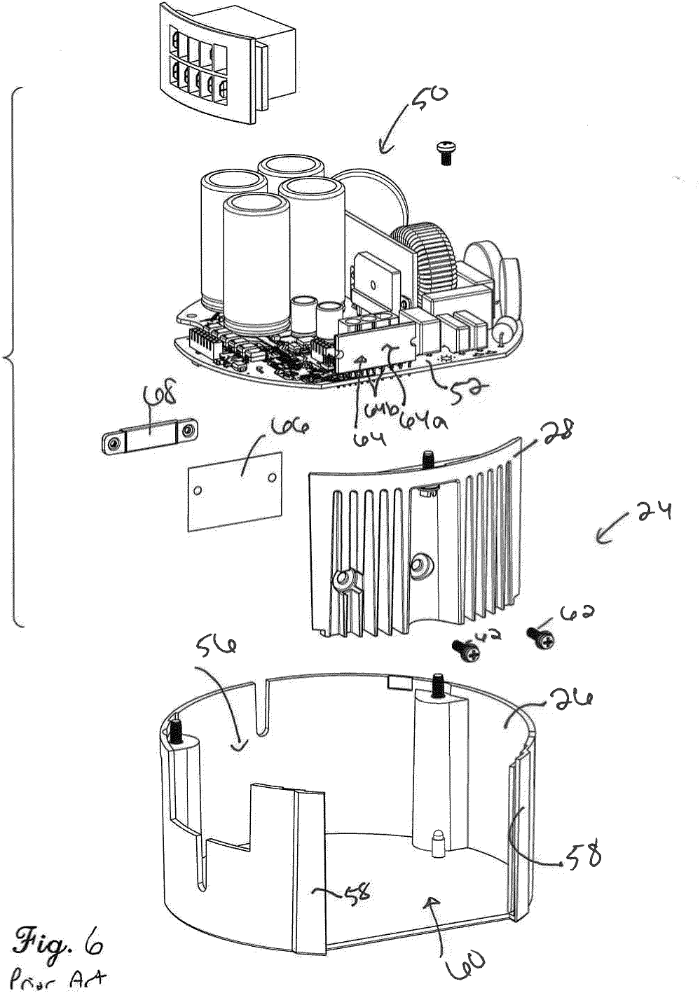

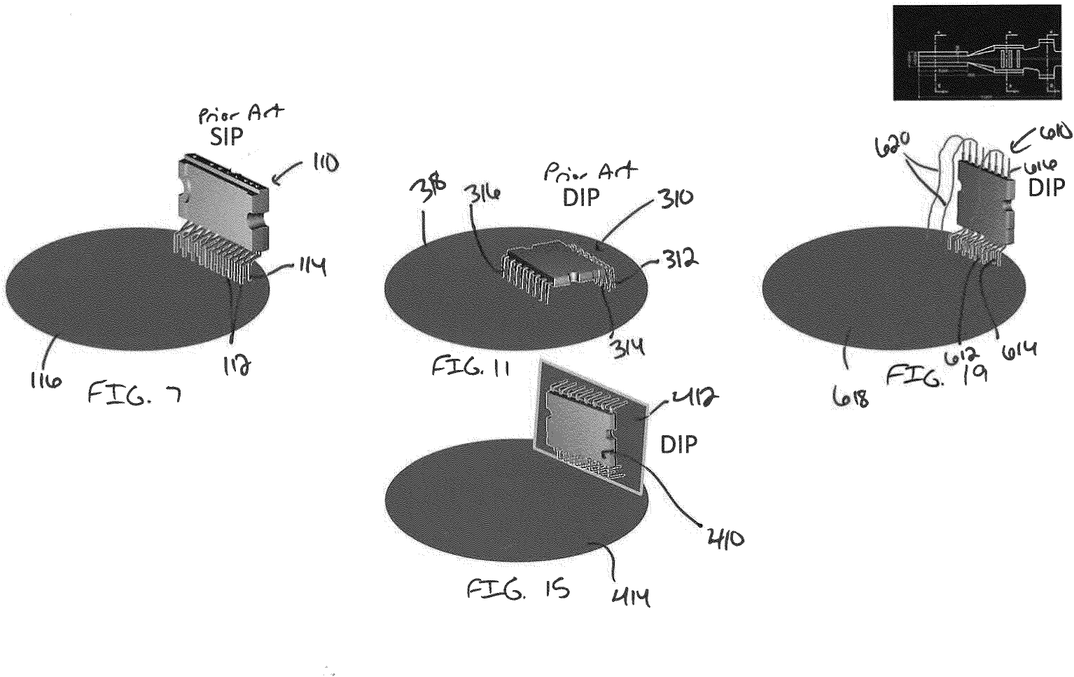

A SIP power module 110 similar to or identical to the power module 64 is shown in greater detail in FIGS. 7-9. The power module 110 includes offset sets of pins 112 and 114 at a bottom end thereof. The pins 112 and 114 are configured for connection with a printed circuit board 116.

FIG. 10 is a photograph of an additional SIP power module 210, similar to the SIP modules 64 and 110, installed on a printed circuit board along with other electronics components of a controller.

### Prior Art DIP Power Module

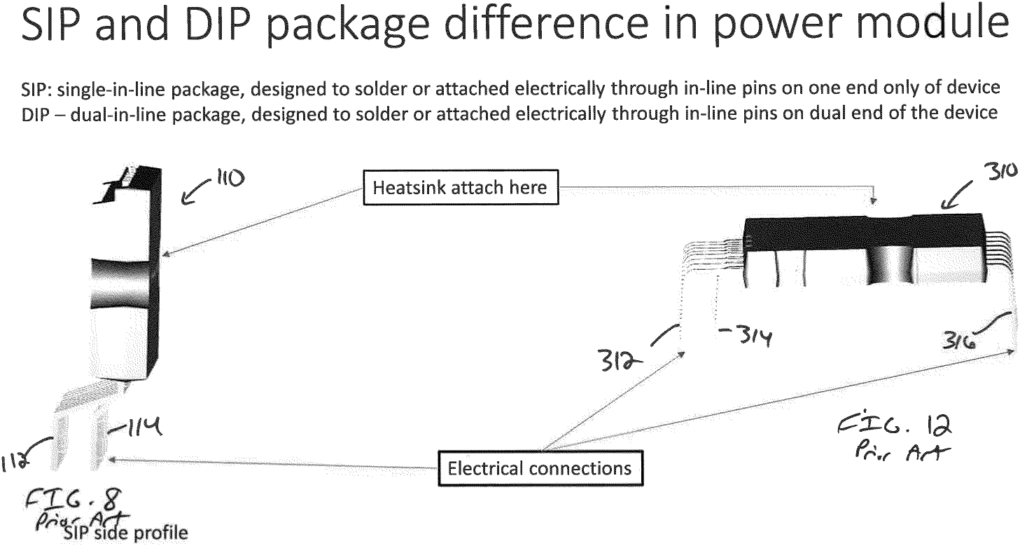

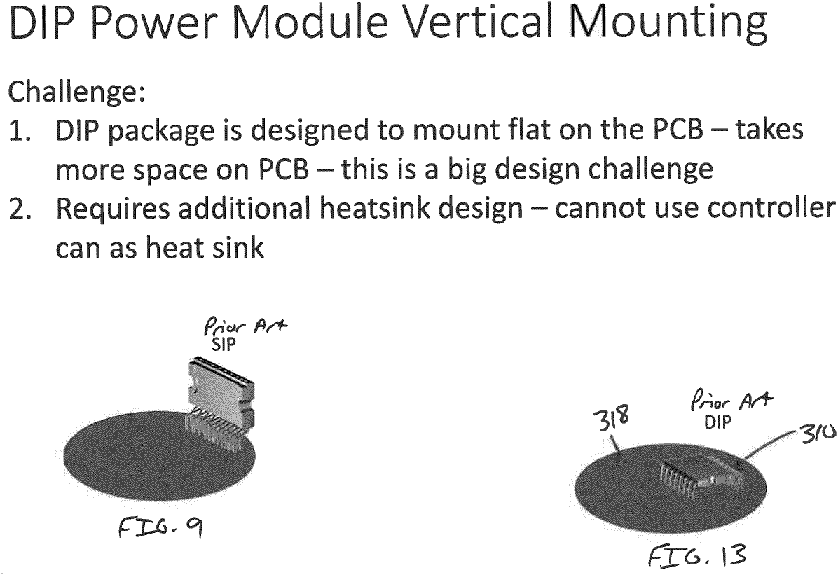

Conventional dual-in-line (DIP) power modules 310, such as that shown in FIGS. 11-14, are characterized by the presence of in-line pins 312, 314, and 316 on dual ends (that is, both ends) of the module 310. More particularly, offset sets of signal connection pins 312 and 314 are disposed at a first end of the module 310. An additional set of power pins 316 is disposed at a second end of the module 310. The pins 312, 314, and 316 are configured for connection with a printed circuit board 318 or an appropriate socket thereon through soldering or other direct or indirect electrical attachment techniques, as will be discussed in greater detail below.

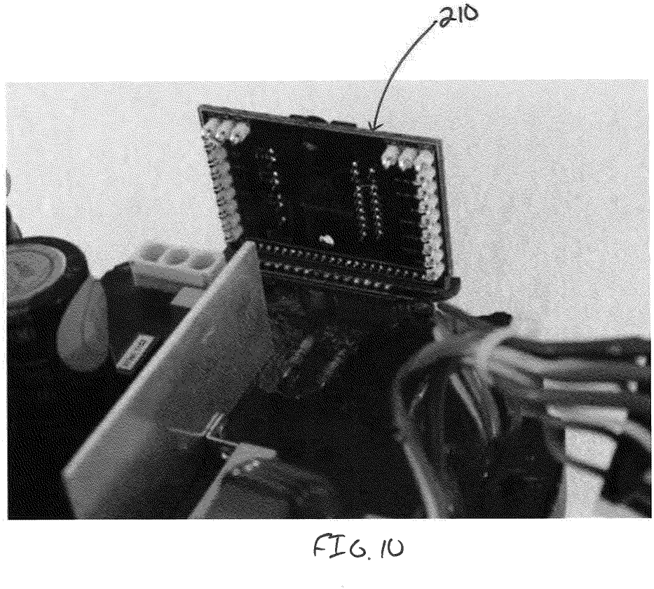

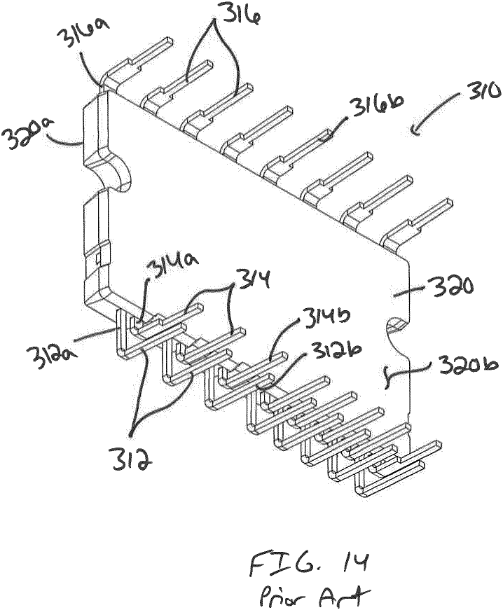

With primary reference to FIG. 14, it is particularly noted that the pins 312, 314, and 316 extend generally orthogonally relative to a body 320 of the module 310. More particularly, the body 320 presents front and back faces 320a and 320b. The pins 312, 314, and 316 include respective base portions 312a, 314a, and 316a proximate the body 320. The pins 312, 314, and 316 likewise include respective end portions 312b, 314b, and 316b distal to the body 320. The base portions 312a, 314a, and 316a extend parallel to and outward from the body 320 (or, more specifically, parallel to the faces 320a and 320b). In contrast, the end portions 312b, 314b, and 316b extend orthogonally or transversely relative to the body 320 (or more specifically, orthogonally or transversely to the faces 320a and 320b).

Mounting of the DIP power module 310 to the PCB 318 in a conventional manner is illustrated schematically in FIGS. 11 and 13. It is noted that such mounting approach requires a substantial mounting space or footprint on the PCB 318 due at least in part to the orthogonal extension of the pins 312, 314, and 316. More particularly, such orthogonal extension of the pins 312, 314, and 316 necessitates a parallel, flat, or overlying (albeit perhaps with space therebetween) arrangement of the body 320 relative to the PCB 318.

### DIP Power Module Mounted to Vertical Plate

In certain applications, including but not limited to certain HVAC controller applications, large space mounting space requirements as conventionally required for DIP power modules (and shown in FIGS. 11 and 13) are incompatible with preferred design layouts. FIGS. 15 and 16 illustrate an approach to overcoming such space and layout constraints using a conventional DIP power module mounted in an unconventional manner.

More particularly, as shown in FIGS. 15 and 16, a conventional DIP power module 410 similar to the previously described DIP power module 310 is mounted to a plate 412. The plate 412 is disposed vertically or, alternatively stated, is positioned transverse to a main PCB 414. The plate 412 may itself be a PCB or may be otherwise appropriately configured. Regardless of specifics, however, the plate 412 should be functionally interconnected with the main PCB 414 to enable appropriate use of the DIP power module 410.

In the illustrated manner, minimal space is taken up on the main PCB 414 despite the use of a conventional DIP power module 410. That is, only a space or footprint on the PCB 414 similar to or only slightly larger than that which would hypothetically be required by the previously described SIP power module 110 is necessary. This footprint is significantly smaller than that which would be required by the conventional DIP power module 310 mounted in the previously described conventional parallel or overlying manner.

### DIP Power Module Mounted Directly and Transverse to Circuit Board - Vertical Top Pins

Although the above-described vertical DIP power module mounting approach solves certain space-constraint problems typically associated with DIP power modules, the use of the additional plate 412 is cumbersome and expensive, in addition to generally increasing complexity. Furthermore, as will be readily apparent to those of ordinary skill in the art, repositioning of leads, addition of components, and/or changes in connections often requires substantial rework of a design or layout in general, with formation of appropriate connections, routes, and so on posing significant challenges. Thermal regulation issues may also arise in association with redesigns. Thus, a solution enabling use of a DIP power module directly in place of an existing SIP power module, with minimal additional rework required and making use of existing thermal regulations techniques and/or structures, is highly desirable.

The controller can 24 of the motor 10 of FIGS. 1-6 is an exemplary controller can for receiving such a novel DIP power module. As noted previously, the controller can 24 in its initial or original configuration receives the SIP power module 64. A desirable novel DIP power module would be configured to be received in at least substantially the same footprint or location as the SIP power module 64 and would also make use of the insert 28 for thermal regulation.

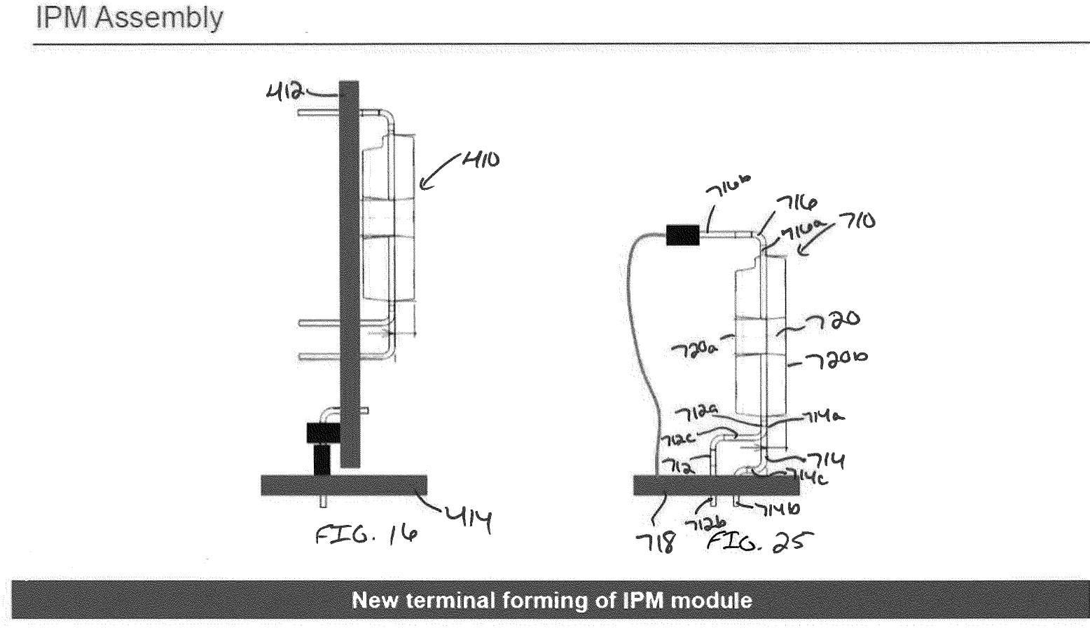

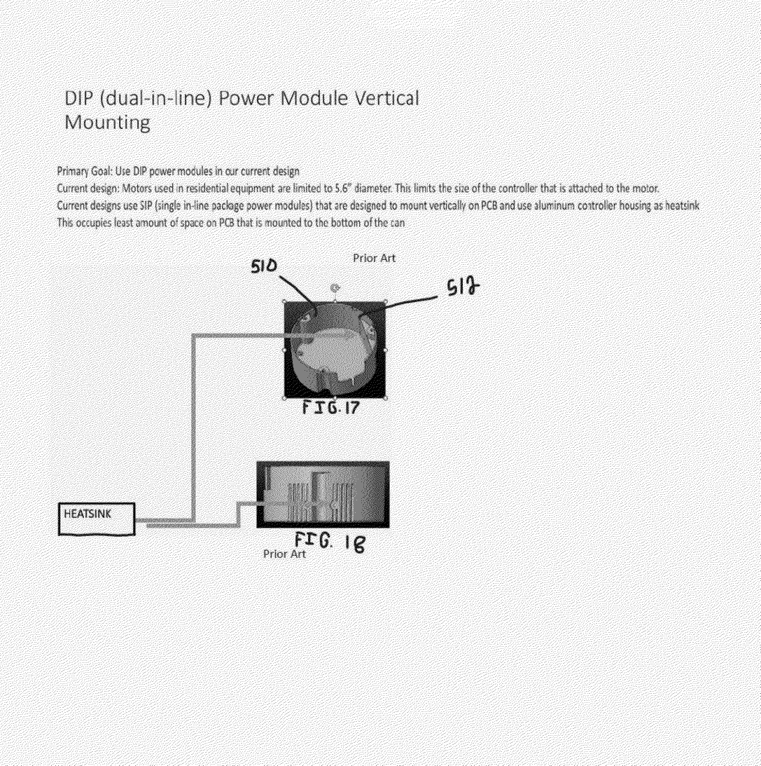

Another exemplary controller can for receiving a novel DIP power module as described above is the controller can 510 of FIGS. 17 and 18. In contrast to the controller can 24, which most preferably includes a can housing 26 comprising polycarbonate and a relatively high thermal conductivity metal insert 28 fixed to the housing 26, the can controller can 510 is generally unitary and formed of aluminum (or another suitable metal or highly conductive material). Although a separate metal insert is not provided, a heat-transferring surface 512 similar to the surface 28a and integral to the design of the controller can 510 provides a suitable heat sink connection for a power module mounted thereto or adjacent thereto.

It is particularly noted that various embodiments of the present invention, including but not limited to those described in detail below, may be used not only with either of the can designs described above (that is, with either the can 24 or the can 510) but also with any of a variety of other suitable can designs. That is, the cans 24 and 510 should be understood to simply be two (2) possible designs for use with the present invention, with many other suitable designs being feasible. Most essentially, as will be discussed in greater detail below, suitable can designs will include a heat transfer surface of a heat sink oriented transverse (or orthogonal or perpendicular) to the associated PCB.

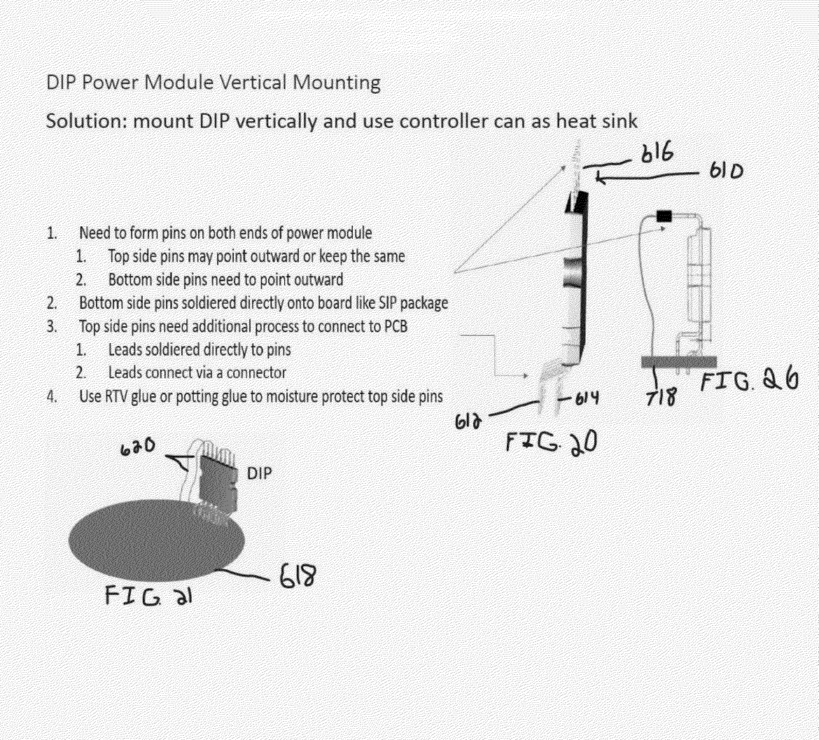

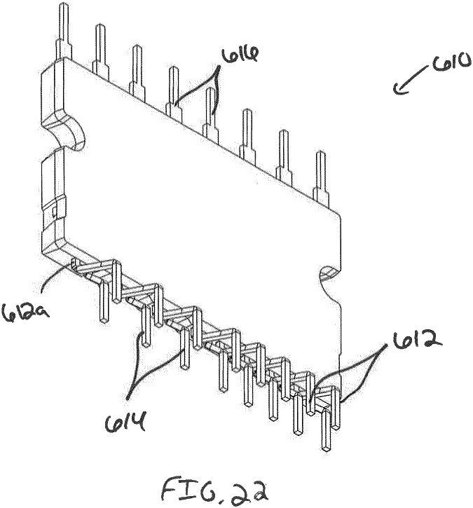

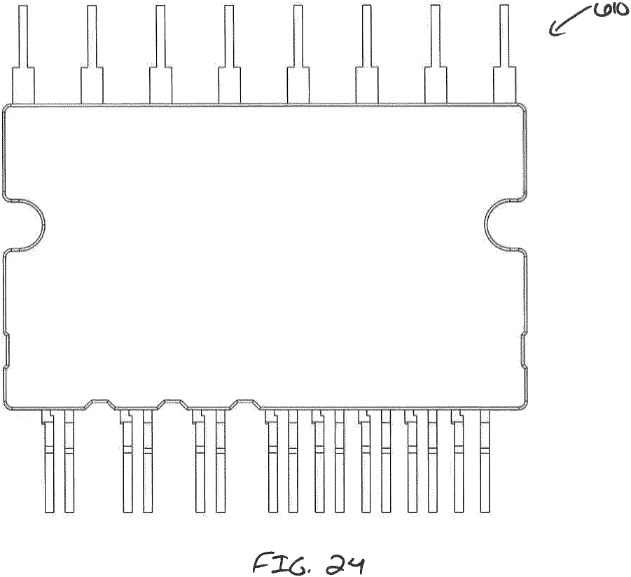

A novel DIP power module 610 suited for such use is illustrated in FIGS. 19-24. The power module 610 includes offset sets of signal connection pins 612 and 614 disposed at a first end (for instance, a bottom end) of the module 610. An additional set of power pins or terminals 616 is disposed at a second end (for instance, a top end) of the module 610. The pins 612, 614, and 616 are configured for connection with a printed circuit board 618 or an appropriate socket thereon through soldering or other direct or indirect electrical attachment techniques, as will be discussed in greater detail below.

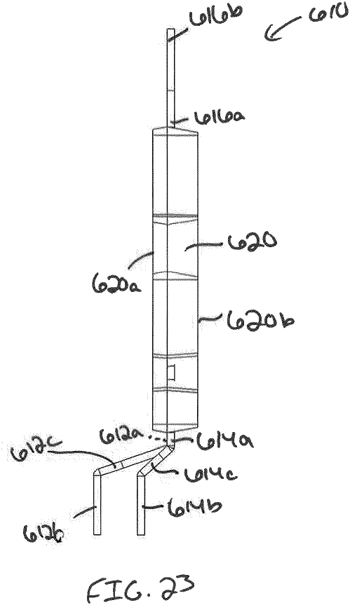

With primary reference to FIG. 23, it is particularly noted that the pins 612, 614, and 616 extend generally outward or parallel relative to a body 620 of the module 610. More particularly, the body 620 presents front and back faces 620a and 620b. The pins 612, 614, and 616 include respective base portions 612a, 614a, and 616a proximate the body 620. The pins 612, 614, and 616 likewise include respective end portions 612b, 614b, and 616b distal to the body 620. The pins 612 and 614 include respective intermediate portions 612c and 614c extending between and interconnecting the base and end portions 612a and 612b, and 614a and 614b, respectively.

The base portions 612a, 614a, and 616a extend parallel to the body 620 or, more specifically, parallel to the faces 620a and 620b. The end portions 612b, 614b, and 616b likewise extend parallel to the body 620 or, more specifically, parallel to the faces 620a and 620b. The intermediate portions 612c and 614c extend obliquely relative to the body 620 and the faces 620a, 620b thereof, in addition to likewise extending obliquely relative to the respective base portions 612a, 614a and end portions 612b, 614b.

Thus, as will be apparent to those of ordinary skill in the art, the lower pins 612 and 614 at least substantially mimic the pins 112 and 114 of the previously described SIP power modules 110 and corresponding pins of the power module 64. The pins 612 and 614 may be conveniently connected to a printed circuit board originally configured for use with a SIP power module, such as the PCB 52 of the previously described motor 10. Furthermore, any heat sink configurations or other features designed for use with the SIP power module 64 or 110 will be well suited for use with the novel DIP power module 610.

For instance, the DIP power module 610 may be positioned in the controller can 24 (in place of the the SIP power module 64) so as to use the metal insert 28 as a heatsink. That is, the body 620 of the power module 610 extends perpendicularly (that is, transversely or orthogonally) relative to or from the PCB 618 and is in thermal communication with the face 28a of the metal insert 28. In another embodiment, the DIP power module 610 may be positioned in the controller can 510, again perpendicular, orthogonal, or transverse to an associated PCB, so as to utilize the surface 512 as a heatsink. A mounting bar (such as the mounting bar 68) or other supplementary mounting provisions (such as the thermal conductive sheet 66) may additionally be utilized without departing from the scope of some aspects of the present invention.

More broadly, the lower pins 612 and 614 are preferably mounted to the PCB 618 in any manner or combination of manners known in the art, including through-holes, sockets, soldering, and so on.

Most preferably, the pins 612 and 614 are additionally potted or otherwise treated for moisture resistance in any manner known in the art and suitable for the present environment.

The upper pins 616 may be indirectly connected to the PCB 618 using a variety of techniques. For instance, in the illustrated embodiment, the upper pins 616 are connected to associated leads 620 via soldering. A soldering process advantageously reduces the contact resistance to a low enough level to handle the electrical current. Without soldering, the contact area and force applied over the leads 620 may potentially be higher than desired.

Alternatively or additionally, the leads might be connected to the upper pins via a connector (not shown).

Regardless of specific connection techniques, it is preferred that room temperature vulcanizing (RTV) glue or potting glue (including but not limited to polyurethane, epoxy, or silicone based potting material) be used to protect the top side pins 616 and connections between the pins 616 and the leads 620 from moisture.

### DIP Power Module Mounted Directly and Transverse to Circuit Board - Bent Top Pins

An alternative novel DIP power module 710 is illustrated in FIGS. 25 and 26. The power module 710, like the power module 610, is oriented perpendicular, orthogonal, or transverse to an associated PCB.

As best shown in FIG. 25, the power module 710 includes offset sets of signal connection pins 712 and 714 disposed at a first end (for instance, a bottom end) of the module 710. An additional set of power pins or terminals 716 are disposed at a second end (for instance, a top end) of the module 710. The pins 712, 714, and 716 are configured for connection with a printed circuit board 718 or an appropriate socket thereon through soldering or other direct or indirect electrical attachment techniques, as will be discussed in greater detail below.

The pins 712 and 714 extend generally outward or parallel relative to a body 720 of the module 710. In contrast, the pins 716 extend generally orthogonally relative to the body 720. More particularly, the body 720 presents front and back faces 720a and 720b. The pins 712, 714, and 716 include respective base portions 712a, 714a, and 716a proximate the body 720. The pins 712, 714, and 716 likewise include respective end portions 712b, 714b, and 716b distal to the body 720. The pins 712 and 714 include respective intermediate portions 712c and 714c extending between and interconnecting the base and end portions 712a and 712b, and 714a and 714b, respectively.

The base portions 712a, 714a, and 716a extend parallel to the body 720 (or, more specifically, parallel to the faces 720a and 720b). The end portions 712b and 714b likewise extend parallel to the body 720 (or, more specifically, parallel to the faces 720a and 720b), with the intermediate portions 712c and 714c extending orthogonally relative to the faces 720a and 720b and orthogonally relative to the respective base portions 712a and 714a. In contrast, the end portions 716b extend orthogonally relative to the faces 720a and 720b.

Thus, the power module 710 differs from the power module 610 primarily in the shape and orientation of the top pins 716. The power module 710 also differs slightly due to the minor variations in the shapes of the bottom pins 712 and 714, although the ends 712b and 714b of the bottom pins 712 and 714 are identically oriented to those of the power module 610.

It is also noted that the power module 710 is illustrated with connectors 720 for attaching leads 722 to the upper terminals 716. However, as noted above, soldering or other techniques are permissible in addition to or in place of connectors.

### DIP Power Module Mounted Directly and Transverse to Circuit Board - Board-In Terminals

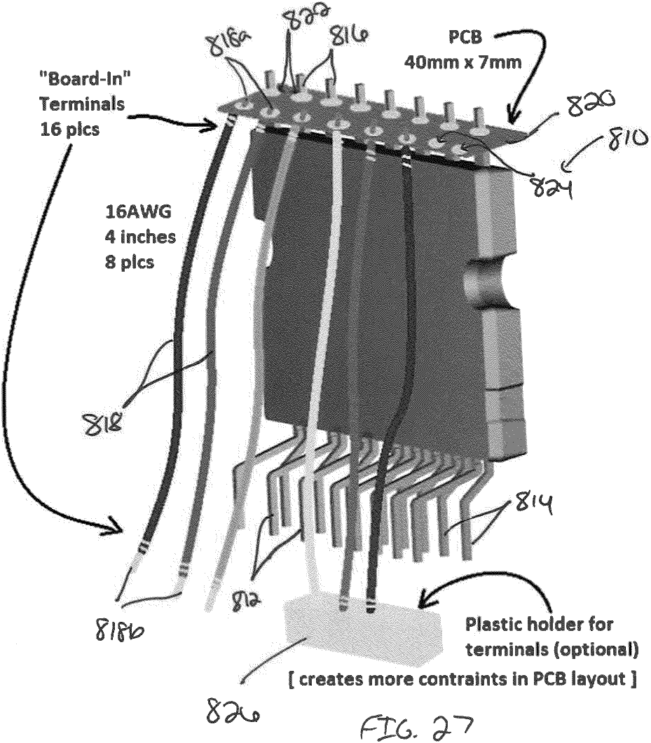

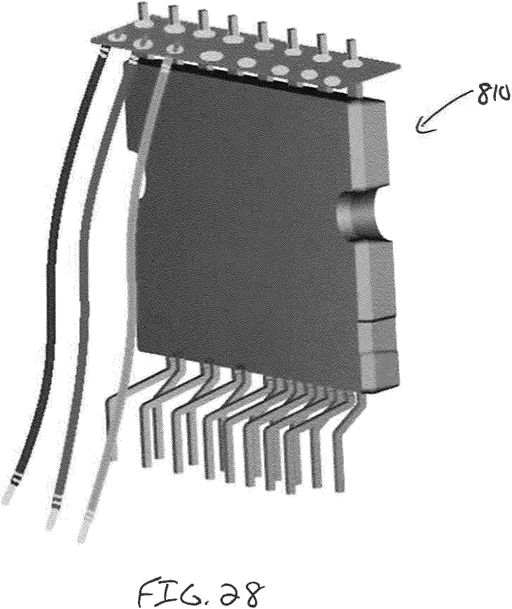

A final embodiment of the present invention is illustrated in FIGS. 27 and 28. In particular, a DIP power module 810 is provided. The power module 810, like the power modules 610 and 710, is oriented perpendicular, orthogonal, or transverse to an associated PCB.

As will be apparent to those or ordinary skill in the art, the power module 810 is configured identically to the power module 610 and thus includes sets of outwardly projecting signal connection pins 812 and 814 and power pins 816.

The power module 810 is configured for connection to a printed circuit board (not shown). More particularly, the pins 812 and 814 may be directly connected to a PCB in any manner described above and/or known in the art. In contrast to the previously described conventional soldering or connecting elements associated with the power pins 616 and 716 of the power modules 610 and 710, however, the power pins or terminals 816 are connected to associated leads 818 via an intermediate board 820.

More particularly, the pins 816 are connected to and support the board 820. In greater detail still, the pins 816 extend through corresponding through holes 822 in the board 820 and are secured thereto via soldering.

The leads 818 each include first and second ends 818a and 818b. The first ends 818a are connected to the board 820. More particularly, the first ends 818a extend through corresponding through holes 824 in the board 820 and are secured thereto via soldering.

The second ends 818b are connected to the PCB or to other elements as appropriate. For instance, as shown in FIG. 27, a plastic holder 826 for terminals to receive the ends 818b may optionally be provided, although space/layout constraints associated with the given PCB may make this option undesirable or difficult.

### Conclusion

The preferred forms of the invention described above are to be used as illustration only and should not be utilized in a limiting sense in interpreting the scope of the present invention. Obvious modifications to the exemplary embodiments, as hereinabove set forth, could be readily made by those skilled in the art without departing from the spirit of the present invention.

It is also noted that certain elements of the various embodiments of the invention as described above are the same as or very similar to those described in detail above in relation to others of the embodiments. Therefore, for the sake of brevity and clarity, redundant descriptions and numbering were generally avoided. Unless otherwise specified, the detailed descriptions of the elements presented above with respect to one of the embodiments should therefore be understood to apply at least generally to the others of the embodiments, as well.

Although the above description presents features of preferred embodiments of the present invention, other preferred embodiments may also be created in keeping with the principles of the invention. Furthermore, these other preferred embodiments may in some instances be realized through a combination of features compatible for use together despite having been presented independently as part of separate embodiments in the above description.

What is claimed is:

1. A motor controller comprising:
a controller housing presenting a heat sink surface;
a printed circuit board at least substantially disposed within said housing; and
a dual-in-line power module thermally engaging said heat sink surface and mounted transverse to said printed circuit board.
